(19) United States
(12) Patent Application Publication
(10) Pub. No.: US 2025/0201698 A1
(43) Pub. Date: Jun. 19, 2025

(54) OFFSET VIA FUSE STRUCTURE IN INTERCONNECT REGION

(71) Applicant: Intel Corporation, Santa Clara, CA (US)

(72) Inventors: Yao-Feng Chang, Bellemont, AZ (US); Szutung Hu, Portland, OR (US)

(73) Assignee: Intel Corporation, Santa Clara, CA (US)

(21) Appl. No.: 18/539,856

(22) Filed: Dec. 14, 2023

(51) Int. Cl. H01L 23/522; H01L 23/532

(52) U.S. Cl. CPC H01L 23/5226; H01L 23/53228; H01L 23/53242; H01L 23/53257

(57) ABSTRACT

Techniques are provided for forming an offset anti-fuse device within the interconnect region over a plurality of field effect transistor (FET) devices. The anti-fuse device can be implemented as a MIM structure within a given interconnect layer. The MIM structure has a first electrode, a dielectric structure on the first electrode, and a second electrode on the dielectric structure. A lower metal line of the interconnect region makes contact with the first electrode and an upper metal line of the interconnect region makes contact with the second electrode. The MIM structure is offset from the upper and/or lower metal lines to reduce the active fuse area between the first and second electrodes. The purposeful misalignment between the electrodes of the MIM structure and the contact metal lines allows for sub-design rule fuse areas to be achieved.

### BACKGROUND

As integrated circuits continue to scale downward in size, a number of challenges arise. Memory structures continue to scale smaller, but complications arise when using relatively high voltages to program some of the elements. For example, there are limitations on how small certain fuse structures can be made, which limits their usefulness. Accordingly, there remain a number of non-trivial challenges with respect to fabricating certain memory-based structures in an integrated circuit.

### BRIEF DESCRIPTION OF THE DRAWINGS

FIG. 1 is a cross-sectional view that illustrates an example portion of an integrated circuit configured with an interconnect region over a plurality of semiconductor devices, in accordance with an embodiment of the present disclosure.

FIG. 2A is a cross-sectional view that illustrates a portion of the interconnect region having a fuse element integrated therewithin, in accordance with an embodiment of the present disclosure.

FIG. 2B is a cross-sectional view that illustrates a portion of an interconnect region having an offset fuse element integrated therewithin, in accordance with another embodiment of the present disclosure.

FIGS. 2C-2F illustrate plan views of the offset between the fuse element and top and bottom metal lines contacting the fuse element, in accordance with some embodiments of the present disclosure.

FIGS. 3A-3G are cross-sectional views that collectively illustrate an example process for forming an offset fuse element in an interconnect region, in accordance with some embodiments of the present disclosure.

FIG. 4 illustrates a schematic of an anti-fuse circuit, in accordance with an embodiment of the present disclosure.

FIG. 5 illustrates a cross-section view of a chip package containing one or more semiconductor dies, in accordance with an embodiment of the present disclosure.

FIG. 6 is a flowchart of a fabrication process for an integrated circuit including an offset fuse element in an interconnect region, in accordance with an embodiment of the present disclosure.

FIG. 7 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein for forming an offset anti-fuse element within the interconnect region over a plurality of field effect transistor (FET) devices. Although the techniques can be used in any number of integrated circuit applications, they are particularly useful with respect to forming metal-insulator-metal (MIM) devices and contacting schemes for size-constrained transistors such as those used in logic and memory cells. Example such cells may include, for instance, memory cells that include an anti-fuse configuration having a memory element and an access device. In some such examples, the anti-fuse elements of such cells are implemented within an interconnect structure. The anti-fuse devices can be implemented as MIM structures within an given interconnect layer. According to some such embodiments, an interconnect layer within a stack of interconnect layers includes a MIM structure having a first electrode, a dielectric structure on the first electrode, and a second electrode on the dielectric structure. A lower metal line of the interconnect region makes contact with the first electrode and an upper metal line of the interconnect region makes contact with the second electrode. According to some embodiments, the MIM structure is offset from the upper and/or lower metal lines to purposefully reduce the active fuse area between the first and second electrodes. A higher fuse yield can be achieved with reduced-area devices. The intentional offset between the electrodes of the MIM structure and the contact metal lines allows for sub-design rule fuse areas to be achieved.

### General Overview

As previously noted above, it can be challenging to provide effective area scaling for fuse structures. A fuse element or memory element may be arranged in series with an access device to provide a one-time programmable bit. These anti-fuse circuits may be used in several applications, such as one-time programmable or reconfigurable read-only-memory (ROM), root-of-trust implementations for memory redundancy, and for on-chip security keys. Anti-fuse circuits use a relatively large voltage (e.g., around 5 V) during a programming operation to cause dielectric breakdown of the gate of the fuse element, thus shorting across the fuse element. Requiring such large programming voltages can be problematic, as it requires thick-gate access transistors. Reducing the size of the fuse (e.g., area between the electrodes) has been shown to potentially lower the programming voltage. However, the size of the fuze is limited by the lithography technology.

Thus, techniques are provided herein for forming MIM-based anti-fuse structures within an interconnect structure that are purposefully offset from contacting metal lines. Although the techniques can be used in any number of applications, they can be used in the context of embedded memory applications, such as a memory array having certain elements formed during backend of line (BEOL) processing. In some such cases, the techniques can be used to provide anti-fuse elements using MIM structures integrated into the interconnect region rather than using FET structures in the device layer. The MIM structure includes a stack of layers that include a first electrode, a dielectric structure on the first electrode, and a second electrode on the dielectric structure. According to some embodiments, the entire MIM structure is incorporated within the thickness of one interconnect layer within a stack of interconnect layers. In some examples, the MIM structure functions as a via within a given interconnect layer between an upper metal line and a lower metal line.

According to some embodiments, the MIM structure is offset from the upper and/or lower metal line to purposefully reduce the effective fuse area of the MIM structure. For example, the MIM structure may be offset by up to 25%, up to 50%, up to 75%, up to 90%, or greater than 99% relative to the top and/or bottom metal lines that contact the first and second electrodes of the MIM structure, respectively. Offsetting the MIM structure allows for the formation of small effective fuse areas that cannot be achieved through standard lithography. Furthermore, according to some embodiments, the degree to which the MIM structure is offset is greater than a standard via misalignment tolerance as dictated by a design standard, such as the via alignment tolerance from the Unified Power Format (UPF) standard. In some examples, the UPF standard allows for a via tolerance of 3σ (or around 99% shifted) and the via offset of the MIM structures described herein are offset by greater than 99%.

According to an embodiment, an integrated circuit includes a plurality of semiconductor devices, an interconnect region above the plurality of semiconductor devices having a plurality of interconnect layers, a first interconnect layer of the plurality of interconnect layers having a first conductive layer, a second interconnect layer of the plurality of interconnect layers and having a second conductive layer, and a via structure extending between the first conductive layer and the second conductive layer. The via structure includes a third conductive layer in contact with the first conductive layer, a fourth conductive layer in contact with the second conductive layer, and a dielectric structure between the third conductive layer and the fourth conductive layer. The via structure is offset from the first conductive layer and second conductive layer such that only a portion of a bottom surface of the third conductive layer contacts the first conductive layer and only a portion of a top surface of the fourth conductive layer contacts the second conductive layer.

According to another embodiment, an integrated circuit includes an interconnect region above a plurality of semiconductor devices with the interconnect region having a plurality of interconnect layers, a first interconnect layer of the plurality of interconnect layers and having a first conductive layer extending along a first direction, a second interconnect layer of the plurality of interconnect layers and having a second conductive layer extending along the first direction, and a third interconnect layer of the plurality of interconnect layers between the first and second interconnect layers. The third interconnect layer includes a dielectric layer and a via structure passing through the dielectric layer in a second direction different from the first direction. The via structure includes a third conductive layer in contact with the first conductive layer, a fourth conductive layer in contact with the second conductive layer, and a dielectric structure between the third conductive layer and the fourth conductive layer. The via structure is offset from the first conductive layer along the second direction and/or is offset from the second conductive layer along the first direction.

According to another embodiment, a method of forming an integrated circuit includes forming a first interconnect layer above a plurality of semiconductor devices and forming a second interconnect layer over the first interconnect layer. Forming the first interconnect layer includes forming a first dielectric layer, forming a trench through the first dielectric layer, and forming a first conductive layer in the trench and extending along a first direction. Forming the second interconnect layer includes forming a second conductive layer on the first conductive layer, forming one or more dielectric layers on the second conductive layer, forming a third conductive layer on the one or more dielectric layers, patterning each of the second conductive layer, one or more dielectric layers, and third conductive layer to form a metal-insulator-metal (MIM) structure on the first conductive layer, such that the MIM structure is offset from the first conductive layer along a second direction different from the first direction; forming a second dielectric layer over the first dielectric layer and over the MIM structure, forming an opening in the second dielectric layer over the MIM structure, such that the opening is offset from the MIM structure along the second direction, and forming a fourth conductive layer in the opening and contacting the third conductive layer of the MIM structure.

The techniques can be used with any type of planar and non-planar transistors, including finFETs (sometimes called double-gate transistors, or tri-gate transistors), nanowire and nanoribbon transistors (sometimes called gate-all-around transistors), and thin film transistors, to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a remove metal gate, or RMG, process). Any number of semiconductor materials can be used in forming the transistors to which power is being supplied by a buried or backside power rail, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate conductive vias or contacts within the interconnect region that include a MIM structure. Such tools may also detect that the MIM structure is offset from top and/or bottom metal lines such that only portions of the top and/or bottom electrodes of the MIM structure contact the corresponding top and/or bottom metal lines. Numerous configurations and variations will be apparent in light of this disclosure.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer.

### Architecture

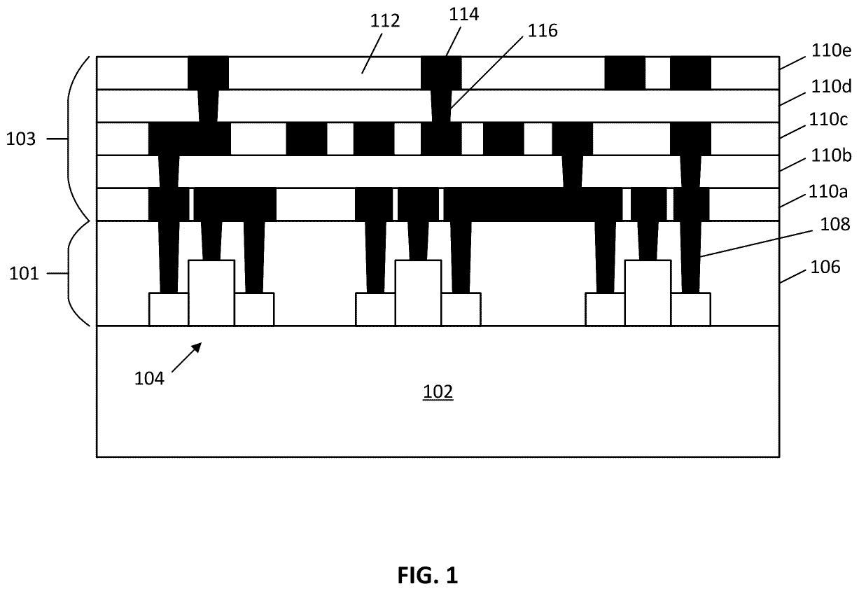

FIG. 1 is a cross-sectional view that illustrates an example portion of an integrated circuit having an interconnect region above a plurality of semiconductor devices, in accordance with an embodiment of the present disclosure. The semiconductor devices in this example are non-planar metal oxide semiconductor (MOS) transistors, such as tri-gate or gate-all-around (GAA) transistors, although other transistor topologies and types can also benefit from the techniques provided herein, as will be appreciated (e.g., planar transistors, thin film transistors, or any other transistors to which contact can be made).

According to some embodiments, the integrated circuit includes a device region 101, and an interconnect region 103 over the device region 101. Device region 101 may include a plurality of semiconductor devices 104 along with one or more other layers or structures associated with the semiconductor devices 104. For example, device region 101 can also include one or more dielectric layers 106 that surround active portions or contacts of the semiconductor devices 104. Device region 101 may also include one or more conductive contacts 108 that provide electrical contact to transistor elements such as gate structures, drain regions, or source regions. Conductive contacts 108 include, for example, tungsten, although other metal or metal alloy materials may be used as well. Conductive contacts may also be a part of, or otherwise include, what is sometimes called a local interconnect, which is considered part of the device layer and usually formed prior to any backend processing.

In some embodiments, device region 101 is formed on or over a substrate 102. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, backside processing is used to remove substrate 102 and form any number of backside interconnect layers.

Interconnect region 103 includes a plurality of interconnect layers 110a-110e stacked over one another. Each interconnect layer can include a dielectric material 112 along with one or more different conductive features. Dielectric material 112 can be any dielectric, such as silicon oxide, silicon oxycarbide, silicon nitride, or silicon oxynitride. Dielectric material 112 may be deposited using any known dielectric deposition technique such as chemical vapor deposition (CVD), plasma-enhanced chemical vapor deposition (PECVD), flowable CVD, spin-on dielectric, or atomic layer deposition (ALD). The one or more conductive features can include conductive traces 114 and conductive vias 116 arranged in any pattern across the interconnect layers 110a-110e to carry signal and/or power voltages to/from the various semiconductor devices 104. A conductive via, such as conductive via 116, may extend through an interconnect layer to connect between conductive traces on an upper interconnect layer and a lower interconnect layer. In other cases, a via 116 may only extend part way through a given interconnect layer. Although interconnect region 103 is illustrated with only five interconnect layers, any number of interconnect layers can be used within interconnect region 103. Also, this example shows vias and lines in different interconnect layers, in both single and dual damascene configurations. In other examples, vias and lines may also exist within the same interconnect layer, such as in the case of some dual damascene configurations.

Any of conductive traces 114 and conductive vias 116 can include any number of conductive materials, with some examples including copper, ruthenium, tungsten, cobalt, molybdenum, and alloys thereof. In some cases, any of conductive traces 114 and conductive vias 116 include a relatively thin liner or barrier, such as titanium nitride, titanium silicide, tungsten carbo-nitride (WCN), PVD or ALD tungsten, or tantalum nitride. As will be discussed in more detail herein, any of conductive vias 116 may include a MIM structure as part of the conductive via to provide an anti-fuse element within interconnect region 103.

It should be noted that each of the various conductive vias 116 and conductive contacts 108 are shown with tapered profiles to indicate a more natural appearance due to the etching process used to form the openings. Any degree of tapering may be observed depending on the etch parameters used and the thickness of the dielectric layer being etched through. Furthermore, conductive vias may be stacked one over the other through different dielectric layers of interconnect region 103. However, in some examples, a single via recess may be formed through more than one dielectric layer yielding a taller, more tapered conductive via that extends through two or more dielectric layers.

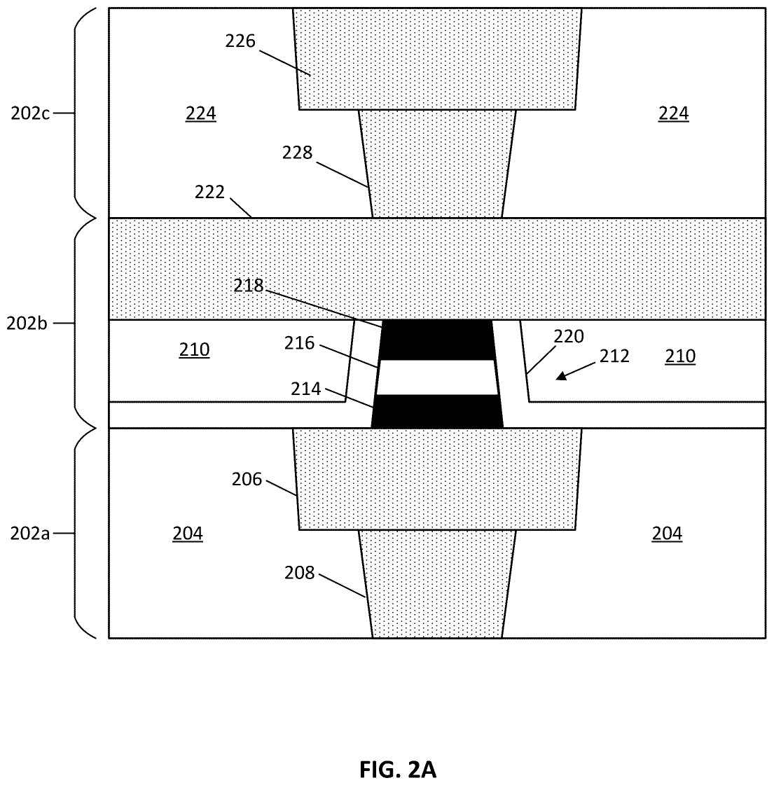

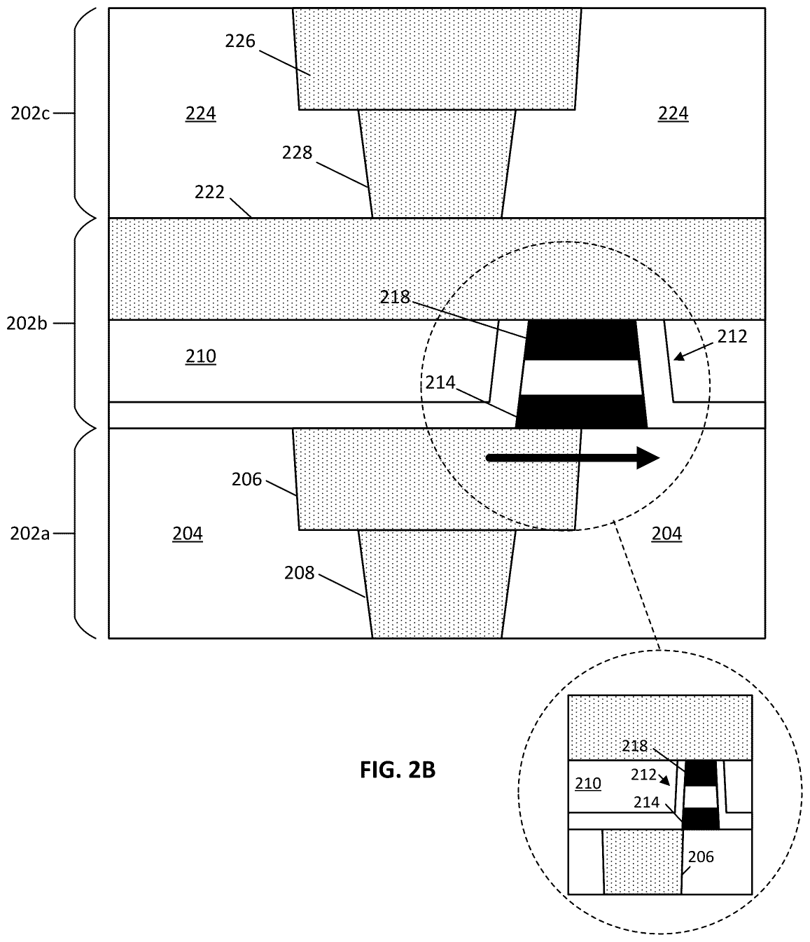

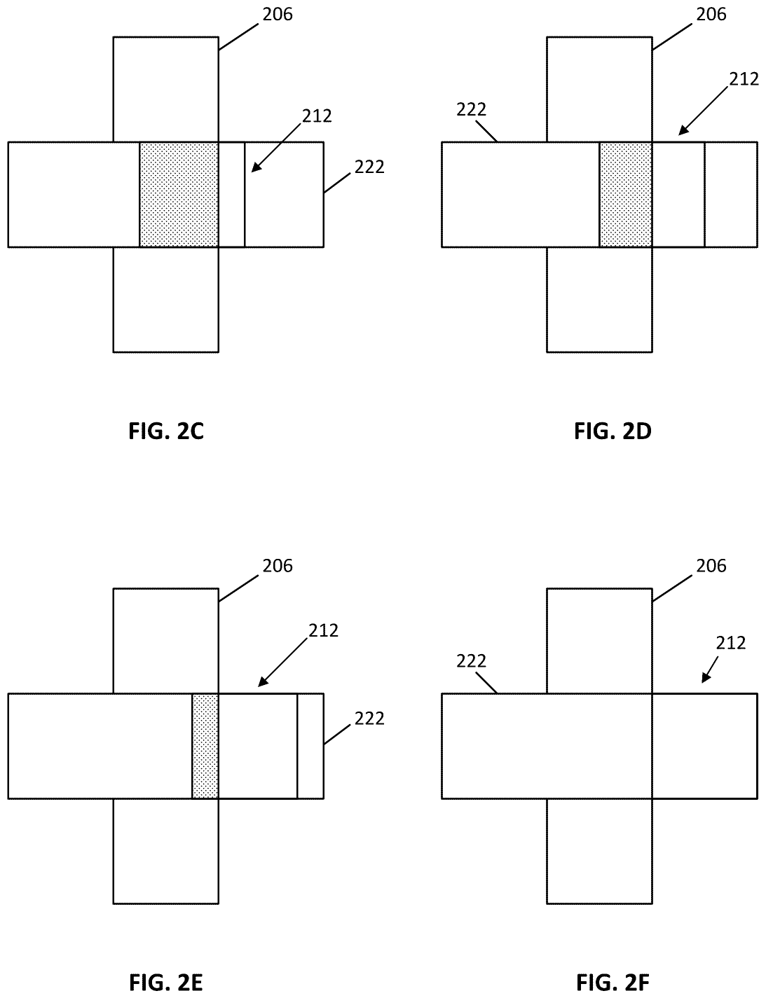

FIG. 2A illustrates a more detailed cross-section view of various interconnect layers of the integrated circuit from FIG. 1, according to an embodiment. The illustrated example includes interconnect layers 202a-202c, although any three sequential interconnect layers could include similar structures discussed herein. Note that these interconnect layers can include via structures and metal lines within a same interconnect layer. Such structures may be formed using a dual damascene process in order to be formed in a single dielectric layer. In other examples, a given interconnect layer may include two dielectric layers to form the via in a first dielectric layer and the metal line separately in a second dielectric layer (e.g., single damascene process). Other features may also be included. For instance, there may be a relatively thin etch stop layer (e.g., silicon nitride having a thickness in the range of 2 nm to 6 nm) between layers 202a and 202b, and between layers 202b and 202c. In such cases, a given conductive interconnect feature can punch through the corresponding etch stop, to provide electrical contract to an underlying conductive interconnect feature. Any number of configurations will be apparent in light of this disclosure.

A first interconnect layer 202a includes a first dielectric region 204, a first conductive layer 206, and a first via 208. First dielectric region 204 may be similar to dielectric material 112, as discussed above, and first conductive layer 206 may be similar to conductive trace 114, as discussed above. In some examples, first dielectric region 204 may be referred to as an interlayer dielectric (ILD), and first conductive layer 206 may be, for instance, a metal line of first interconnect layer 202a. The metal line may be, for instance, a conductive trace that is longer in the y-direction (into and/or out of page) than it is wide in the x-direction (left to right), but may also be relatively short such as a contact pad that is square in shape as viewed in the x-y plane rather than rectangular. First via 208 may be similar to via 116, as discussed above. First conductive layer 206 and first via 208 may be formed together using a dual damascene process, or formed as separate elements in separate dielectric layers using a single damascene process.

According to some embodiments, a second interconnect layer 202b on first interconnect layer 202a includes a second dielectric region 210 and a via structure 212 that is made up of various layers. Second dielectric region 210 may be similar to first dielectric region 204 and may include any number of dielectric layers having the same material composition (e.g., silicon dioxide, or other ILD material). As further shown in this example, via structure 212 includes a MIM structure having a first metal layer 214 (or first electrode), a dielectric structure 216, and a second metal layer 218 (or second electrode). In some embodiments, one or more additional conductive layers may be formed beneath first metal layer 214, such that the one or more additional conductive layers are between first metal layer 214 and first conductive layer 206.

In some examples, first metal layer 214 and second metal layer 218 include any one of platinum, tungsten, gold, or titanium, although other conductive materials may be used. First metal layer 214 and second metal layer 218 may have substantially the same thickness (e.g., between about 7 nm and about 13 nm), but they need not be the same in all cases. Dielectric structure 216 may represent any number of dielectric layers. In some examples, dielectric structure 216 has a thickness between about 5 nm and about 10 nm, and may be a single dielectric layer. Dielectric structure 216 may include a layer of silicon dioxide.

According to some embodiments, a dielectric liner 220 may cover the sidewalls of the MIM structure. Thus, dielectric liner 220 may be present along sidewalls of each of first metal layer 214, dielectric structure 216, and second metal layer 218. In some examples, dielectric liner 220 may include silicon nitride and may have a thickness between about 5 nm and about 10 nm. Other examples may use other dielectric liners (e.g., silicon carbide, silicon oxynitride, silicon oxycarbide, silicon oxycarbonitride).

According to some embodiments, second interconnect layer 202b includes a second conductive layer 222. Second conductive layer 222 may be similar to first conductive layer 206 and may include the same conductive material (e.g., a metal line or conductive trace). In some examples, second conductive layer 222 represents a metal layer that is one level above the metal layer represented by first conductive layer 206, although it may be two or more layers thereabove. In any case, second conductive layer 222 may extend through a portion of dielectric region 210 to contact second metal layer 218. In this way, first conductive layer 206 acts as a bottom contact or landing pad for the MIM structure and second conductive layer 222 acts as a top contact for the MIM structure. According to some embodiments, first conductive layer 206 and second conductive layer 222 extend lengthwise in orthogonal directions to one another, such that via structure 212 extends between first conductive layer 206 and second conductive layer 222 at the intersection of first conductive layer 206 and second conductive layer 222 (such as shown in FIG. 2A). In some other embodiments, first conductive layer 206 and second conductive layer 222 each extend lengthwise along the same direction (e.g., into and out of the page, or across the page) within the interconnect region.

In some examples, a third interconnect layer 202c is provided over second interconnect layer 202b and includes a third dielectric region 224, a third conductive layer 226, and a second via 228. Third conductive layer 226 and second via 228 may be substantially similar to first conductive layer 206 and first via 208.

FIG. 2B illustrates via structure 212 from FIG. 1 offset from first conductive layer 206, according to some embodiments. Due to the offset, only a portion of first metal layer 214 lands on or otherwise contacts first conductive layer 206. In some embodiments, via structure 212 is offset from both first conductive layer 206 and second conductive layer 222 (e.g., offset in both the X and Y directions). The portion of via structure 212 that is overlapped by first conductive layer 206 controls the effective fuse size that is used when programming or reading the memory bit. The effective fuse area is represented by the cross-sectional area of the overlapped portion of via structure 212, which is less than the total cross-sectional area of via structure 212. By intentionally misaligning via structure 212, smaller anti-fuse elements can be made compared to those that can be made by using conventional lithography alone. As further shown in the dashed circle pull-out of FIG. 2B, the misalignment can be in excess of 99% misaligned, leaving a very small contact area of less than 1% (e.g., 0.9999% to 0.0001%).

FIGS. 2C-2F illustrate top-down views of various degrees of offset between via structure 212 and first and second conductive layers 206/222. Note in these examples that first and second conductive layers 222/226 extend orthogonally to one another. In FIG. 2C, via structure 212 has been shifted along the X direction, such that around 75% of the area of via structure 212 overlaps (represented by the shaded region) with first conductive layer 206. In FIG. 2D, via structure 212 has been shifted along the X direction, such that around 50% of the area of via structure 212 overlaps (represented by the shaded region) with first conductive layer 206. In FIG. 2E, via structure 212 has been shifted along the X direction, such that around 25% of the area of via structure 212 overlaps (represented by the shaded region) with first conductive layer 206. In FIG. 2F, via structure 212 has been shifted along the X direction, such that only an edge of via structure 212 (e.g., an area of less than about 1%, such as 0.9999% to 0.0001%) overlaps with first conductive layer 206. Any degree of offset may be used such that, for example, at least 25%, at least 50%, at least 75%, or at least 99% of the surface area of first metal layer 214 does not contact first conductive layer 206. Although only one offset MIM structure has been described in FIGS. 2B-2F above, any number of similar MIM structures may be formed within the same interconnect layer and/or within any number of other interconnect layers to create an array of anti-fuse elements. Additionally, via structure 212 may be offset in the Y direction only such that, for example, at least 25%, at least 50%, at least 75%, or at least 99% of the surface area of second metal layer 218 does not contact second conductive layer 222. In some embodiments, via structure 212 may be offset in both the X and Y directions to affect the amount of overlap with both first conductive layer 206 and second conductive layer 222.

### Fabrication Methodology

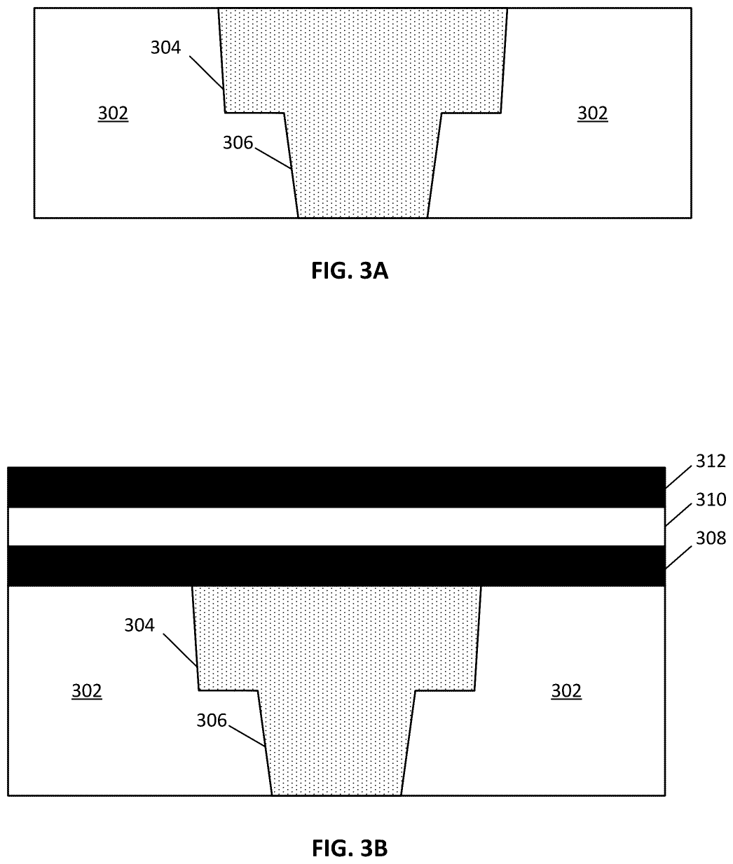

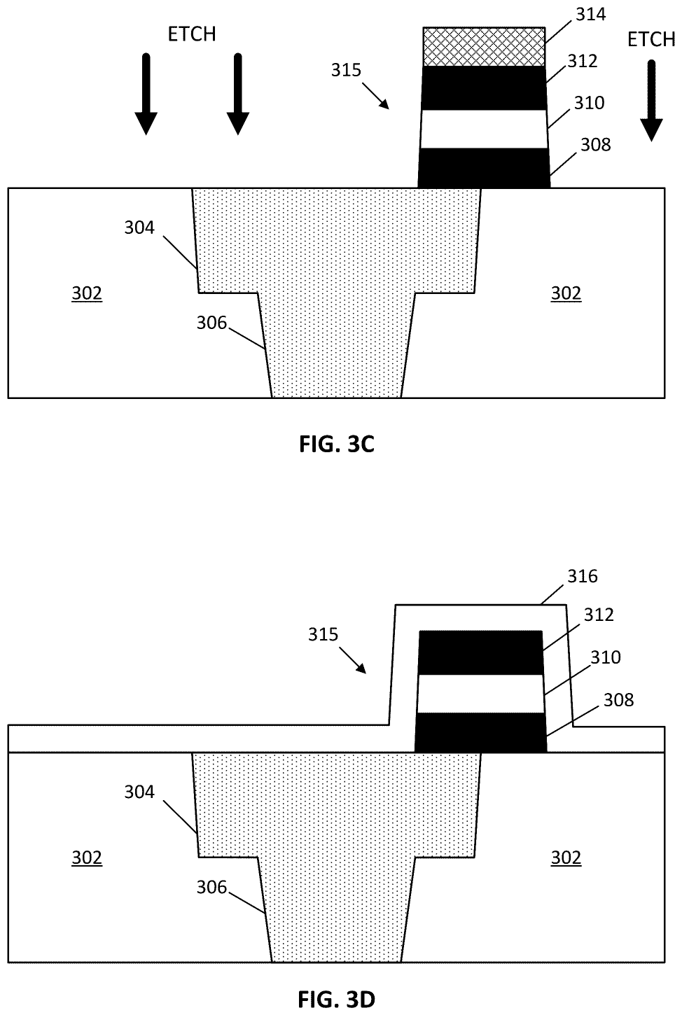

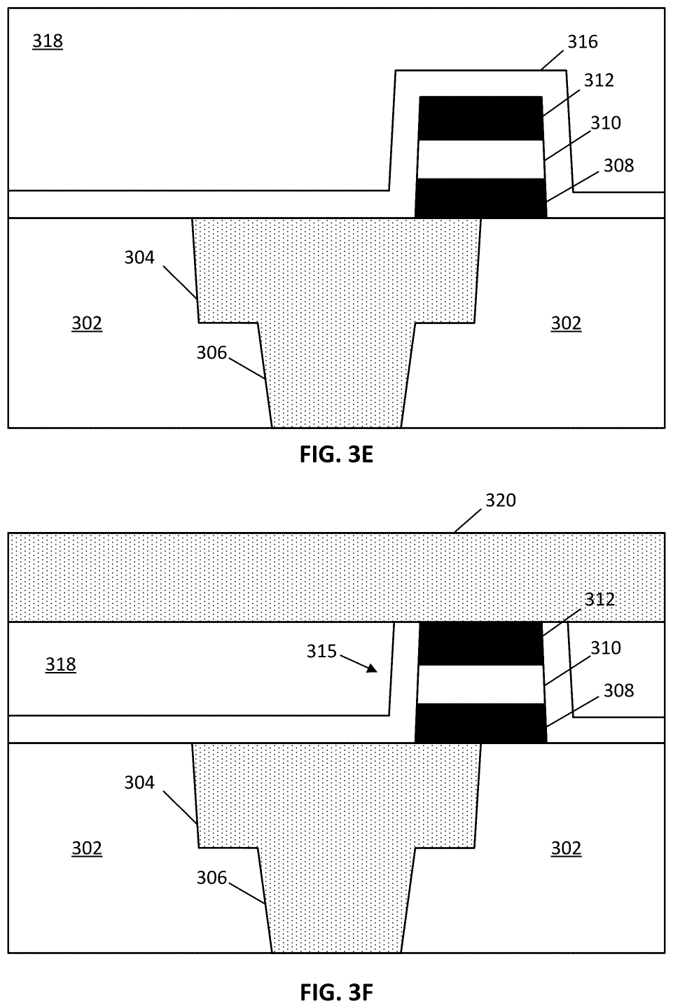

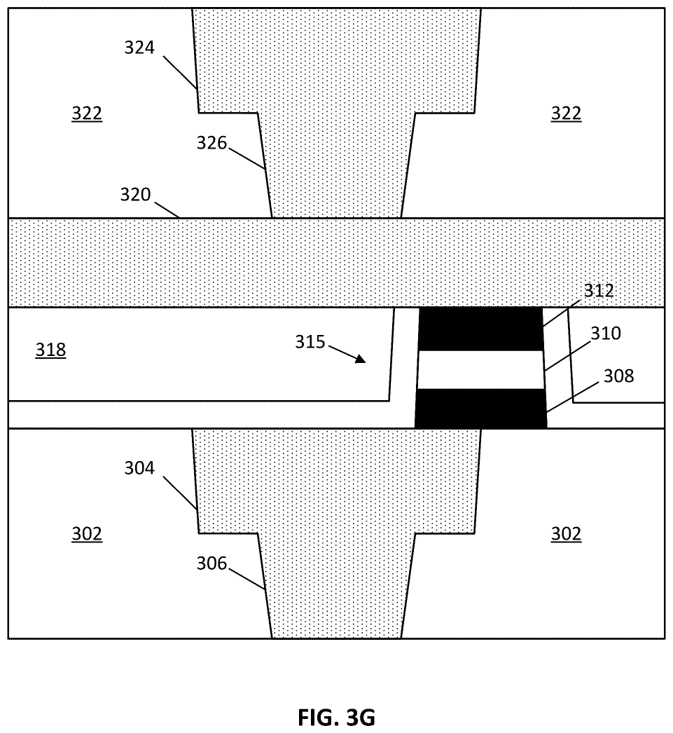

FIGS. 3A-3G are cross-sectional views that collectively illustrate an example process for forming a portion of an interconnect region of an integrated circuit, in accordance with an embodiment of the present disclosure. Each figure shows an example structure that results from the process flow up to that point in time, so the depicted structure evolves as the process flow continues, culminating in the structure shown in FIG. 3G, which is similar to the structure illustrated in FIG. 2B. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIG. 3A is a cross sectional view taken through a first interconnect layer of a plurality of stacked interconnect layers. Accordingly, the illustrated first interconnect layer may be at any position within interconnect region 103. The first interconnect layer includes a first dielectric region 302 that may include one or more dielectric layers having a suitable dielectric material, such as silicon oxide, silicon oxynitride, silicon nitride, or silicon oxycarbide. First dielectric region 302 may be deposited using any known dielectric deposition technique, such as CVD, PECVD, flowable CVD, spin-on dielectric, or ALD. First dielectric region 302 may have a height between about 30 nm and about 70 nm.

According to some embodiments, an opening is formed through first dielectric region 302 and a first conductive layer 304 and a first via 306 are formed within the opening. The opening may be formed using one or more anisotropic etching techniques, such as using reactive ion etching (RIE) while masking the unetched regions of first dielectric region 302 with either a photoresist or hard mask. First conductive layer 304 and first via 306 may be formed together (e.g., dual damascene process) or first via 306 may be formed first with first conductive layer 304 formed separately over first via 306 (e.g., single damascene process).

According to some embodiments, first conductive layer 304 and first via 306 include copper or tungsten that is deposited using any one of electroplating, electroless plating, CVD, or PECVD, to name a few examples. Any other suitable conductive materials may be used as well (e.g., aluminum, ruthenium). After deposition of at least first conductive layer 304, a polishing process may be performed using, for example, chemical mechanical polishing (CMP) to planarize a top surface of both first conductive layer 304 and first dielectric region 302. In some embodiments, a thin barrier layer is deposited along the inner surfaces of the opening prior to the formation of first conductive layer 304 and/or first via 306. The thin barrier layer may include, for example, titanium or tantalum (e.g., titanium nitride or tantalum nitride, having a thickness in the range of 2 nm to 6 nm). In some examples, an etch stop layer may be provided prior to forming the next interconnect layer. The etch stop layer may include, for example, a nitride or carbide or other suitable dielectric material (e.g., silicon nitride having a thickness in the range of 2 nm to 6 nm).

FIG. 3B is a cross sectional view of the structure depicted in FIG. 3A, after formation of various material layers over the first interconnect layer. In some embodiments, a first metal layer 308 is formed over the first interconnect layer, a dielectric structure 310 is formed on first metal layer 308, and a second metal layer 312 is formed on dielectric structure 310. First metal layer 308 may be formed directly on first conductive layer 304. In some other examples, any number of other conductive layers are present between first metal layer 308 and first conductive layer 304. If a non-conductive layer is present over first conductive layer 304 (such as an etch stop layer), then lithography can be used to create an opening in the non-conductive layer over first conductive layer 304, so that first metal layer 308 can conductively contact the underlying first conductive layer 304 or some intervening conductive layer, as the case may be. Each of first metal layer 308, dielectric structure 310, and second metal layer 312 may be deposited using any suitable deposition technique, such as CVD, ALD, PECVD, or physical vapor deposition (PVD).

In some examples, first metal layer 308 and second metal layer 312 may each include any one of platinum, tungsten, gold, or titanium to provide bottom and top electrodes, respectively, of an anti-fuse element. Dielectric structure 310 may include any number of dielectric layers, such as a single layer of silicon dioxide. In some examples, both first metal layer 308 and second metal layer 312 may have a thickness of around 10 nm, and dielectric structure 310 may have a thickness between about 5 nm and about 10 nm.

FIG. 3C is a cross sectional view of the structure depicted in FIG. 3B, after formation of masking layer 314 and an etching process to form a MIM structure 315 from first metal layer 308, dielectric structure 310, and second metal layer 312. Masking layer 314 may be any suitable photoresist or hard mask material (e.g., nitride or carbide). An anisotropic etching process may be used to etch away portions of first metal layer 308, dielectric structure 310, and second metal layer 312 that are not protected by masking layer 314. Note that the resulting MIM structure 315 may have sidewalls that taper outward slightly due to effects from the etching process. The etch may be controlled to stop once first dielectric region 302 has been exposed, however, some portion of first dielectric region 302 and/or first conductive layer 304 may be removed as well by the etching process (e.g., if not covered by an etch stop).

According to some embodiments, MIM structure 315 is offset from first conductive layer 304, such that a first portion of MIM structure 315 is aligned over first conductive layer 304 while a second portion of MIM structure 315 is not aligned over first conductive layer 304. As noted above, the degree of offset or misalignment dictates the resulting effective size of the anti-fuse element. MIM structure 315 may be offset such that at least 10%, at least 25%, at least 50%, at least 75%, or at least 99% of the bottom area of first metal layer 308 does not contact first conductive layer 304 (e.g., extends past an edge of first conductive layer 304).

FIG. 3D is a cross sectional view of the structure depicted in FIG. 3C, after formation of a dielectric liner 316 over MIM structure 315, according to some embodiments. Dielectric liner 316 may be deposited using any suitable conformal deposition technique, such as CVD or ALD, and includes a dielectric material. In some examples, dielectric liner 316 includes silicon nitride and has a thickness between about 5 nm and about 10 nm.

FIG. 3E is a cross sectional view of the structure depicted in FIG. 3D, after formation of a second dielectric region 318 over MIM structure 315. Second dielectric region 318 may include one or more dielectric layers having a suitable dielectric material, such as silicon oxide, silicon oxynitride, silicon nitride, or silicon oxycarbide. Second dielectric region 318 may be deposited using any known dielectric deposition technique, such as CVD, PECVD, flowable CVD, spin-on dielectric, or ALD. In some examples, second dielectric region 318 may have a height between about 30 nm and about 70 nm, although such height can vary from one embodiment to the next. According to some embodiments, second dielectric region 318 represents the dielectric region of a second interconnect layer above the first interconnect layer. A top surface of second dielectric region 318 may be polished using, for example, CMP to planarize its top surface (e.g., to remove any bump or other topology caused by the presence of the MIM structure.

FIG. 3F is a cross sectional view of the structure depicted in FIG. 3E, after the formation of a second conductive layer 320 through a portion of second dielectric region 318, according to some embodiments. An opening is formed through a portion of second dielectric region 318 and through a portion of dielectric liner 316 to expose at least a portion of second metal layer 312. The opening may be formed using any anisotropic etching technique, such as using RIE while masking the unetched regions of second dielectric region 318 with either a photoresist or hard mask. The RIE etching process may etch through both second dielectric region 318 and dielectric liner 316, and any other intervening layer that may be present (e.g., an etch stop layer).

Second conductive layer 320 may include copper, aluminum, ruthenium, tungsten, or any other conductive material that is deposited using any one of electroplating, electroless plating, CVD, or PECVD, to name a few examples. After deposition of second conductive layer 320, a polishing process may be performed using, for example, CMP to planarize a top surface of both second conductive layer 320 and second dielectric region 318. In some embodiments, a thin barrier layer is deposited along the inner surfaces of the opening prior to the formation of second conductive layer 320. The thin barrier layer may include, for instance, titanium or tantalum and may be considered an integral part of second conductive layer 320. Second conductive layer 320 may extend lengthwise (e.g., across the page) orthogonally compared to first conductive layer 304.

According to some embodiments, MIM structure 315 is not offset from second conductive layer 320 (e.g., not offset into and out of the page). In some embodiments, MIM structure 315 is offset from second conductive layer 320 (e.g., into or out of the page), such that a first portion of MIM structure 315 is aligned over second conductive layer 320 while a second portion of MIM structure 315 is not aligned over second conductive layer 320. MIM structure 315 may be offset such that at least 10%, at least 25%, at least 50%, at least 75%, or at least 99% of the top area of second metal layer 312 does not contact second conductive layer 320 (e.g., extends past an edge of second conductive layer 320 into or out of the page).

FIG. 3G is a cross sectional view of the structure depicted in FIG. 3F, after formation of a third interconnect layer on the second interconnect layer, according to an embodiment of the present disclosure. The third interconnect layer includes a third dielectric region 322 that may include one or more dielectric layers having a suitable dielectric material, such as silicon oxide, silicon oxynitride, silicon nitride, or silicon oxycarbide. Third dielectric region 322 may be deposited using any known dielectric deposition technique, such as CVD, PECVD, flowable CVD, spin-on dielectric, or ALD. Third dielectric region 322 may have a height between about 30 nm and about 70 nm.

According to some embodiments, an opening is formed through third dielectric region 322 and a third conductive layer 324 and a second via 326 are formed within the opening. The opening may be formed using one or more anisotropic etching techniques, such as using reactive ion etching (RIE) while masking the unetched regions of third dielectric region 322 with either a photoresist or hard mask. Third conductive layer 324 and second via 326 may be formed together (e.g., dual damascene process) or second via 326 may be formed first with third conductive layer 324 formed separately over second via 326 (e.g., single damascene process). Third conductive layer 324 and second via 326 may be substantially similar to first conductive layer 304 and first via 306, respectively.

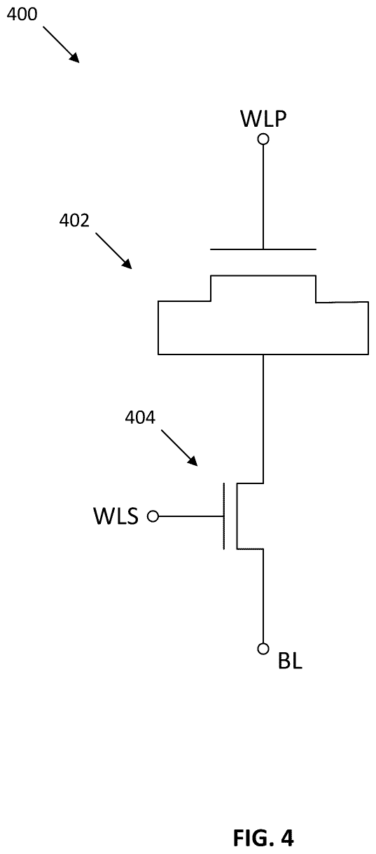

FIG. 4 illustrates an example schematic of an anti-fuse circuit 400, according to some embodiments. Anti-fuse circuit 400 includes a memory element 402 in series with an access device 404. Memory element 402 may include any number of FET devices with their source and drain terminals shorted together, such that the only conductive path that exists through memory element 402 is through the gate dielectric following dielectric breakdown.

According to some embodiments, memory element 402 includes an anti-fuse structure with two conductors on either side of a dielectric region, such as MIM structure 315 discussed above. In some such cases, access device 404 may be formed on top of (or below) the MIM structure 315, either in the same interconnect layer or in the upper or lower interconnect layer, so as to provide a memory cell within the interconnect structure. Any number of such memory cells can be formed within the overall interconnect structure. When a high enough potential is applied across memory element 402, by way of the word line (WL) and bit line (BL), such as around 5.0 V, dielectric breakdown of memory element 402 occurs and effectively shorts memory element 402. This can be done during a programming operation. Due to the reduced effective size of the anti-fuse element using the techniques discussed herein, this programming voltage may be lowered to a level around 2.0 V. Any number of anti-fuse circuits can be densely arrayed to provide permanent ‘0’ or ‘1’ bits depending on the state of memory element 402. For instance, memory element 402 provides a ‘0’ in its non-shorted state, and a ‘1’ in its shorted state. In any case, the stored value can subsequently be read out, during a read operation.

In more detail, prior to being programmed, memory element 402 has capacitor-like qualities (two conductive plates sandwiching a dielectric material). A program voltage (e.g., 2.0 V) can be applied via the WL corresponding to that bitcell, and lower voltage can be applied to the BL (e.g., ground). During such a programming operation, the access device 404 of that bitcell is forward biased so as to allow current to flow on the corresponding WL and through memory element 402 of that bitcell to the corresponding BL. The access device of other bitcells in the same row as the bitcell being programmed are reverse-biased by an appropriate voltage provided on their corresponding BLs. Likewise, the access device of other bitcells in the same column as the bitcell being programmed are reverse-biased by an appropriate voltage provided on their corresponding WLs. So, one bitcell can be programmed (or read) at a time. Once programmed, the memory element 402 effectively acts as a resistor. During a read operation, a read voltage (e.g., something lower than programming voltage) can be applied via the WL and BL corresponding to that bitcell, and the resistance of the memory element 402 operates in conjunction with a resistance of a readout circuit so as to provide an indication of its programmed value (either a ‘1’ or a ‘0’, as the case may be).

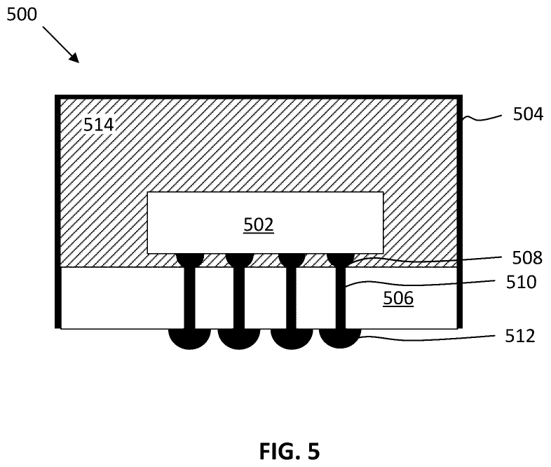

FIG. 5 illustrates an example embodiment of a chip package 500, in accordance with an embodiment of the present disclosure. As can be seen, chip package 500 includes one or more dies 502. One or more dies 502 may include at least one integrated circuit having a structure as described in any of the aforementioned embodiments. One or more dies 502 may include any other circuitry used to interface with other devices formed on the dies, or other devices connected to chip package 500, in some example configurations.

As can be further seen, chip package 500 includes a housing 504 that is bonded to a package substrate 506. The housing 504 may be any standard or proprietary housing, and may provide, for example, electromagnetic shielding and environmental protection for the components of chip package 500. The one or more dies 502 may be conductively coupled to a package substrate 506 using connections 508, which may be implemented with any number of standard or proprietary connection mechanisms, such as solder bumps, ball grid array (BGA), pins, or wire bonds, to name a few examples. Package substrate 506 may be any standard or proprietary package substrate, but in some cases includes a dielectric material having conductive pathways (e.g., including conductive vias and lines) extending through the dielectric material between the faces of package substrate 506, or between different locations on each face. In some embodiments, package substrate 506 may have a thickness less than 1 millimeter (e.g., between 0.1 millimeters and 0.5 millimeters), although any number of package geometries can be used. Additional conductive contacts 512 may be disposed at an opposite face of package substrate 506 for conductively contacting, for instance, a printed circuit board (PCB). One or more vias 510 extend through a thickness of package substrate 506 to provide conductive pathways between one or more of connections 508 to one or more of contacts 512. Vias 510 are illustrated as single straight columns through package substrate 506 for ease of illustration, although other configurations can be used (e.g., damascene, dual damascene, through-silicon via, or an interconnect structure that meanders through the thickness of substrate 506 to contact one or more intermediate locations therein). In still other embodiments, vias 510 are fabricated by multiple smaller stacked vias, or are staggered at different locations across package substrate 506. In the illustrated embodiment, contacts 512 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 512, to inhibit shorting.

In some embodiments, a mold material 514 may be disposed around the one or more dies 502 included within housing 504 (e.g., between dies 502 and package substrate 506 as an underfill material, as well as between dies 502 and housing 504 as an overfill material). Although the dimensions and qualities of the mold material 514 can vary from one embodiment to the next, in some embodiments, a thickness of mold material 514 is less than 1 millimeter. Example materials that may be used for mold material 514 include epoxy mold materials, as suitable. In some cases, the mold material 514 is thermally conductive, in addition to being electrically insulating.

### Methodology

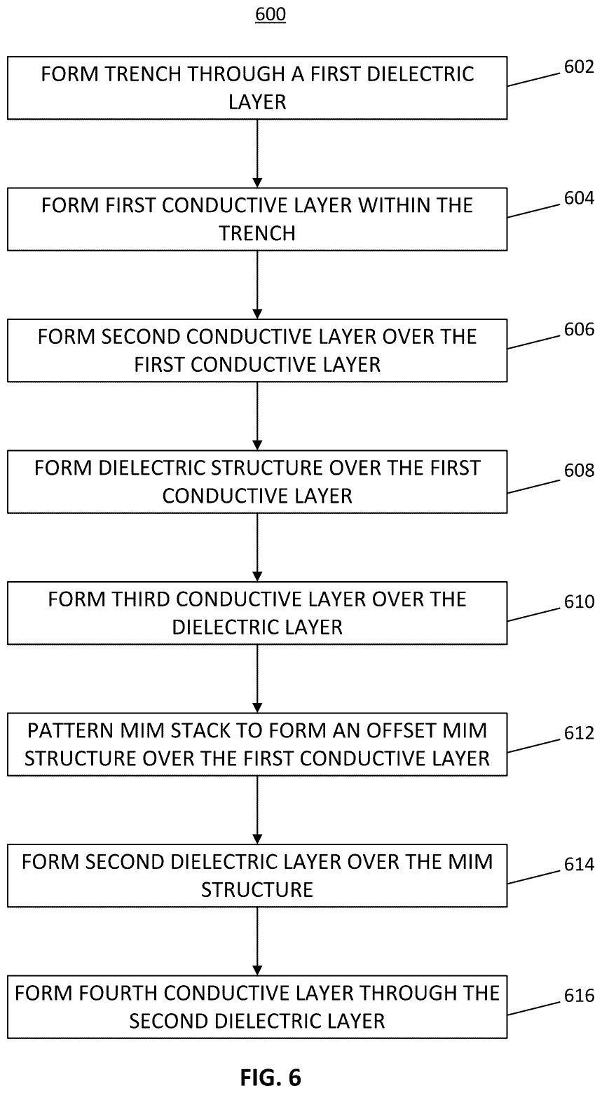

FIG. 6 is a flow chart of a method 600 for forming at least a portion of an integrated circuit, according to an embodiment. Various operations of method 600 may be illustrated in FIGS. 3A-3G. However, the correlation of the various operations of method 600 to the specific components illustrated in the aforementioned figures is not intended to imply any structural and/or use limitations. Rather, the aforementioned figures provide one example embodiment of method 600. Other operations may be performed before, during, or after any of the operations of method 600. Some of the operations of method 600 may be performed in a different order than the illustrated order. In some embodiments, the various operations of method 600 are performed during back end-of-the-line (BEOL) processing, although other applications may benefit from the techniques described herein, including memory and logic cells in frontside or backside interconnect structures, or cells within a device layer.

Method 600 begins with operation 602 where a trench opening is formed through a first dielectric layer. In some examples, the trench opening exposes an underlying conductive feature (e.g., via, line, or device contact). The first dielectric layer may be part of an interconnect layer within a plurality of stacked interconnect layers above a plurality of semiconductor devices. The first dielectric layer may be any dielectric material, such as silicon oxide, silicon oxynitride, silicon nitride, or silicon oxycarbide, and may be deposited using any known dielectric deposition technique, such as CVD, PECVD, flowable CVD, spin-on dielectric, or ALD. The trench opening may be formed using an anisotropic etching technique, such as RIE.

Method 600 continues with operation 604 where a first conductive layer is formed within the trench opening. The first conductive layer may include copper, tungsten, or any other suitable conductive material, that is deposited using any one of electroplating, electroless plating, CVD, or PECVD, to name a few examples. After deposition of the first conductive layer, a polishing process may be performed using, for example, CMP to planarize a top surface of both the first conductive layer and the first dielectric layer. In some embodiments, a thin barrier layer is deposited along the inner surfaces of the trench opening prior to the formation of the first conductive layer.

Method 600 continues with operation 606 where a second conductive layer is formed over the first conductive layer. According to some embodiments, the second conductive layer is also formed over the first dielectric layer. The second conductive layer may include, for example, any one of platinum, tungsten, gold, or titanium and may be deposited using any suitable metal deposition technique. In some examples, the second conductive layer has a thickness of around 10 nm, although geometries may vary from one example to the next.

Method 600 continues with operation 608 where a dielectric structure is formed over the second conductive layer. The dielectric structure represents one or more dielectric layers and may be formed directly on the second conductive layer using any suitable deposition technique, such as CVD. The dielectric structure may include a single layer of silicon dioxide. The dielectric structure may have a thickness between about 5 nm and about 10 nm.

Method 600 continues with operation 610 where a third conductive layer is formed over the dielectric structure. The third conductive layer may be formed directly on the dielectric structure using any suitable metal deposition technique. The third conductive layer may include, for instance, any one of platinum, tungsten, gold, or titanium and may be deposited using any suitable metal deposition technique. According to some embodiments, the third conductive layer and the second conductive layer have substantially the same properties.

Method 600 continues with operation 612 where the MIM stack of the second conductive layer, dielectric structure, and third conductive layer are patterned to form an MIM structure that is offset over the first conductive layer. The MIM structure may be a part of a via structure formed over the first conductive layer. A masking layer may be used to protect a portion of the MIM stack while the exposed portions of the MIM stack are etched away using any suitable anisotropic etching process. The resulting MIM structure may have a largest plan area (e.g., plan area across the second conductive layer) between about 0.45 μm² and about 1 μm².

According to some embodiments, the MIM structure is shifted partially off of the lower first conductive layer such that a first portion of the second conductive layer contacts the first conductive layer while a second portion of the second conductive layer does not contact the first conductive layer. The MIM structure may be shifted such that at least 10%, at least 25%, at least 50%, at least 75%, or at least 99% of the plan area of the second conductive layer does not contact the first conductive layer (e.g., extends past an edge of the first conductive layer). In some embodiments, the total plan area of the second conductive layer that directly contacts the first conductive layer may be less than 0.75 μm², less than 0.64 μm², less than 0.50 μm², or less than 0.16 μm².

In some embodiments, a dielectric liner is formed over the MIM structure. In some examples, the dielectric liner includes silicon nitride and has a thickness between about 5 nm and about 10 nm.

Method 600 continues with operation 614 where a second dielectric layer is formed over the MIM structure. The second dielectric layer may be any dielectric material, such as silicon oxide, silicon oxynitride, silicon nitride, or silicon oxycarbide and may be deposited using any known dielectric deposition technique. According to some embodiments, the second dielectric layer and the first dielectric layer may have substantially the same properties. The second dielectric layer may represent the dielectric layer of a second interconnect layer above the first interconnect layer.

Method 600 continues with operation 616 where an opening is formed through a portion of the second dielectric layer and a fourth conductive layer is formed within the opening to contact the MIM structure. The opening may be formed using any anisotropic etching technique, such as using RIE while masking the unetched regions of the second dielectric layer with either a photoresist or hard mask. The RIE etching process may etch through both the second dielectric layer and through the dielectric liner to expose a top portion of the MIM structure (e.g., a portion of the third conductive layer). The fourth conductive layer may have substantially the same properties as the first conductive layer.

After deposition of the fourth conductive layer, a polishing process may be performed using, for example, CMP to planarize a top surface of both the fourth conductive layer and the second dielectric layer. According to some embodiments, the MIM structure is purposefully offset or misaligned beneath the fourth conductive structure. For example, the MIM structure may be shifted such that at least 10%, at least 25%, at least 50%, at least 75%, or at least 99% of the plan area of the third conductive layer does not contact the fourth conductive layer (e.g., extends past an edge of the fourth conductive layer). In some embodiments, the total plan area of the third conductive layer that directly contacts the fourth conductive layer may be less than 0.75 μm², less than 0.64 μm², less than 0.50 μm², or less than 0.16 μm².

### Example System

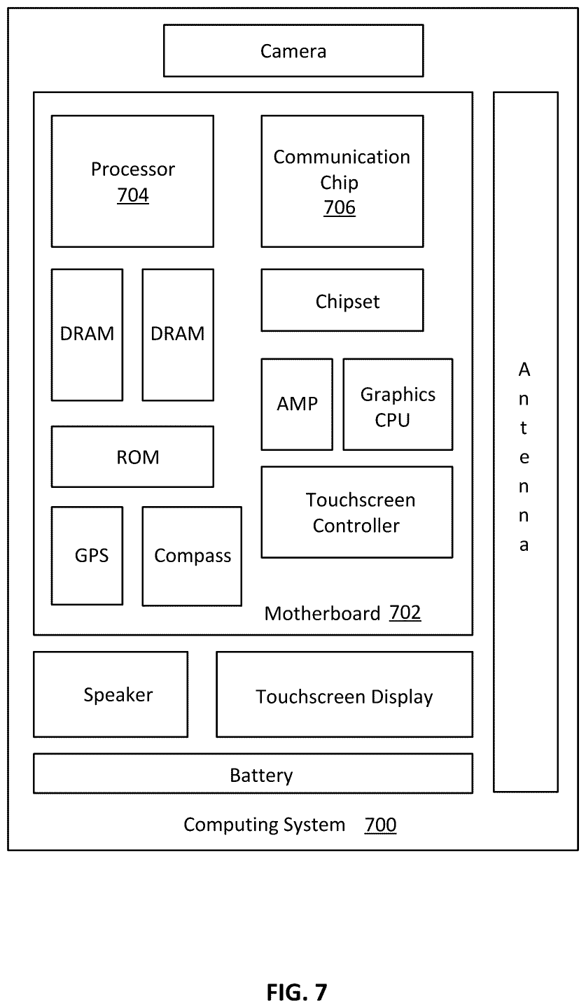

FIG. 7 is an example computing system implemented with one or more of the integrated circuit structures as disclosed herein, in accordance with some embodiments of the present disclosure. As can be seen, the computing system 700 houses a motherboard 702. The motherboard 702 may include a number of components, including, but not limited to, a processor 704 and at least one communication chip 706, each of which can be physically and electrically coupled to the motherboard 702, or otherwise integrated therein. As will be appreciated, the motherboard 702 may be, for example, any printed circuit board (PCB), whether a main board, a daughterboard mounted on a main board, or the only board of system 700, etc.

Depending on its applications, computing system 700 may include one or more other components that may or may not be physically and electrically coupled to the motherboard 702. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 700 may include one or more integrated circuit structures or devices configured in accordance with an example embodiment (e.g., a module including an integrated circuit having interconnect structures that have one or more offset MIM structures integrated in the interconnect region). In some embodiments, multiple functions can be integrated into one or more chips (e.g., for instance, note that the communication chip 706 can be part of or otherwise integrated into the processor 704).

The communication chip 706 enables wireless communications for the transfer of data to and from the computing system 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing system 700 includes an integrated circuit die packaged within the processor 704. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 706 also may include an integrated circuit die packaged within the communication chip 706. In accordance with some such example embodiments, the integrated circuit die of the communication chip includes one or more semiconductor devices as variously described herein. As will be appreciated in light of this disclosure, note that multi-standard wireless capability may be integrated directly into the processor 704 (e.g., where functionality of any chips 706 is integrated into processor 704, rather than having separate communication chips). Further note that processor 704 may be a chip set having such wireless capability. In short, any number of processor 704 and/or communication chips 706 can be used. Likewise, any one chip or chip set can have multiple functions integrated therein.

In various implementations, the computing system 700 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 700 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a plurality of semiconductor devices, an interconnect region above the plurality of semiconductor devices having a plurality of interconnect layers, a first interconnect layer of the plurality of interconnect layers having a first conductive layer, a second interconnect layer of the plurality of interconnect layers and having a second conductive layer, and a via structure extending between the first conductive layer and the second conductive layer. The via structure includes a third conductive layer in contact with the first conductive layer, a fourth conductive layer in contact with the second conductive layer, and a dielectric structure between the third conductive layer and the fourth conductive layer. The via structure is offset from the first conductive layer and second conductive layer such that only a portion of a bottom surface of the third conductive layer contacts the first conductive layer and only a portion of a top surface of the fourth conductive layer contacts the second conductive layer.

Example 2 includes the integrated circuit of Example 1, wherein the dielectric structure comprises a layer comprising silicon and oxygen.

Example 3 includes the integrated circuit of Example 1 or 2, wherein the dielectric structure has a thickness between about 5 nm and about 10 nm.

Example 4 includes the integrated circuit of any one of Examples 1-3, wherein the first conductive layer and the second conductive layer each comprise copper or tungsten.

Example 5 includes the integrated circuit of any one of Examples 1-4, wherein the third conductive layer and the fourth conductive layer each comprise any one of platinum, tungsten, gold, or titanium.

Example 6 includes the integrated circuit of any one of Examples 1-5, wherein the via structure is offset by at least 25% such that at least 25% of the bottom surface of the third conductive layer does not contact the first conductive layer, and/or at least 25% of the top surface of the fourth conductive layer does not contact the second conductive layer.

Example 7 includes the integrated circuit of any one of Examples 1-5, wherein the via structure is offset by at least 50% such that at least 50% of the bottom surface of the third conductive layer does not contact the first conductive layer, and/or at least 50% of the top surface of the fourth conductive layer does not contact the second conductive layer.

Example 8 includes the integrated circuit of any one of Examples 1-5, wherein the via structure is offset by at least 99% such that less than 1% of the bottom surface of the third conductive layer contacts the first conductive layer, and/or less than 1% of the top surface of the fourth conductive layer contacts the second conductive layer.

Example 9 is a printed circuit board that includes the integrated circuit of any one of Examples 1-8.

Example 10 is an integrated circuit that includes an interconnect region above a plurality of semiconductor devices with the interconnect region having a plurality of interconnect layers, a first interconnect layer of the plurality of interconnect layers and having a first conductive layer extending along a first direction, a second interconnect layer of the plurality of interconnect layers and having a second conductive layer extending along the first direction, and a third interconnect layer of the plurality of interconnect layers between the first and second interconnect layers. The third interconnect layer includes a dielectric layer and a via structure passing through the dielectric layer in a second direction different from the first direction. The via structure includes a third conductive layer in contact with the first conductive layer, a fourth conductive layer in contact with the second conductive layer, and a dielectric structure between the third conductive layer and the fourth conductive layer. The via structure is offset from the first conductive layer along the second direction and/or is offset from the second conductive layer along the first direction.

Example 11 includes the integrated circuit of Example 10, wherein the dielectric structure comprises a layer comprising silicon and oxygen.

Example 12 includes the integrated circuit of Example 10 or 11, wherein the dielectric structure has a thickness between about 5 nm and about 10 nm.

Example 13 includes the integrated circuit of any one of Examples 10-12, wherein the first conductive layer and the second conductive layer each comprise copper or tungsten.

Example 14 includes the integrated circuit of any one of Examples 10-13, wherein the third conductive layer and the fourth conductive layer each comprise any one of platinum, tungsten, gold, or titanium.

Example 15 includes the integrated circuit of any one of Examples 10-14, wherein the via structure is offset along the second direction by at least 25% such that at least 25% of a bottom surface of the third conductive layer does not contact the first conductive layer, and/or the via structure is offset along the first direction by at least 25% such that at least 25% of a top surface of the fourth conductive layer does not contact the second conductive layer.

Example 16 includes the integrated circuit of any one of Examples 10-14, wherein the via structure is offset along the second direction by at least 50% such that at least 50% of a bottom surface of the third conductive layer does not contact the first conductive layer, and/or the via structure is offset along the first direction by at least 50% such that at least 50% of a top surface of the fourth conductive layer does not contact the second conductive layer.

Example 17 includes the integrated circuit of any one of Examples 10-14, wherein the via structure is offset along the second direction by at least 99% such that less than 1% of a bottom surface of the third conductive layer contacts the first conductive layer, and/or the via structure is offset along the first direction by at least 99% such that less than 1% of a top surface of the fourth conductive layer contacts the second conductive layer.

Example 18 includes the integrated circuit of any one of Examples 10-17, wherein the third direction is orthogonal to the first and second directions.

Example 19 is a printed circuit board that includes the integrated circuit of any one of Examples 10-18.

Example 20 is an electronic device that includes a chip package having one or more dies. At least one of the one or more dies includes a plurality of semiconductor devices, an interconnect region above the plurality of semiconductor devices having a plurality of interconnect layers, a first interconnect layer of the plurality of interconnect layers having a first conductive layer, a second interconnect layer of the plurality of interconnect layers and having a second conductive layer, and a via structure extending between the first conductive layer and the second conductive layer. The via structure includes a third conductive layer in contact with the first conductive layer, a fourth conductive layer in contact with the second conductive layer, and a dielectric structure between the third conductive layer and the fourth conductive layer. The via structure is offset from the first conductive layer and second conductive layer such that only a portion of a bottom surface of the third conductive layer contacts the first conductive layer and only a portion of a top surface of the fourth conductive layer contacts the second conductive layer.

Example 21 includes the electronic device of Example 20, wherein the dielectric structure comprises a layer comprising silicon and oxygen.

Example 22 includes the electronic device of Example 20 or 21, wherein the dielectric structure has a thickness between about 5 nm and about 10 nm.

Example 23 includes the electronic device of any one of Examples 20-22, wherein the first conductive layer and the second conductive layer each comprise copper or tungsten.

Example 24 includes the electronic device of any one of Examples 20-23, wherein the third conductive layer and the fourth conductive layer each comprise any one of platinum, tungsten, gold, or titanium.

Example 25 includes the electronic device of any one of Examples 20-24, wherein the via structure is offset by at least 25% such that at least 20% of the bottom surface of the third conductive layer does not contact the first conductive layer, and/or at least 25% of the top surface of the fourth conductive layer does not contact the second conductive layer.

Example 26 includes the electronic device of any one of Examples 20-24, wherein the via structure is offset by at least 50% such that at least 50% of the bottom surface of the third conductive layer does not contact the first conductive layer, and/or at least 50% of the top surface of the fourth conductive layer does not contact the second conductive layer.

Example 27 includes the electronic device of any one of Examples 20-24, wherein the via structure is offset by at least 99% such that less than 1% of the bottom surface of the third conductive layer contacts the first conductive layer, and/or less than 1% of the top surface of the fourth conductive layer contacts the second conductive layer.

Example 28 includes the electronic device of any one of Examples 20-27, further comprising a printed circuit board, wherein the chip package is attached to the printed circuit board.

Example 29 is a method of forming an integrated circuit. The method includes forming a first interconnect layer above a plurality of semiconductor devices and forming a second interconnect layer over the first interconnect layer. Forming the first interconnect layer includes forming a first dielectric layer, forming a trench through the first dielectric layer, and forming a first conductive layer in the trench and extending along a first direction. Forming the second interconnect layer includes forming a second conductive layer on the first conductive layer, forming one or more dielectric layers on the second conductive layer, forming a third conductive layer on the one or more dielectric layers, patterning each of the second conductive layer, one or more dielectric layers, and third conductive layer to form a metal-insulator-metal (MIM) structure on the first conductive layer, such that the MIM structure is offset from the first conductive layer along a second direction different from the first direction; forming a second dielectric layer over the first dielectric layer and over the MIM structure, forming an opening in the second dielectric layer over the MIM structure, such that the opening is offset from the MIM structure along the second direction, and forming a fourth conductive layer in the opening and contacting the third conductive layer of the MIM structure.

Example 30 includes the method of Example 29, wherein the first conductive layer and the fourth conductive layer each comprises copper or tungsten.

Example 31 includes the method of Example 29 or 30, wherein the second conductive layer and the third conductive layer each comprises any one of platinum, tungsten, gold, or titanium.

Example 32 includes the method of any one of Examples 29-31, wherein forming the one or more dielectric layers comprises forming at least one layer comprising silicon and oxygen.

Example 33 includes the method of any one of Examples 29-32, wherein forming the one or more dielectric layers comprises forming one or more dielectric layers having a thickness between about 5 nm and about 10 nm.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit, comprising:
a plurality of semiconductor devices;
an interconnect region above the plurality of semiconductor devices, the interconnect region comprising a plurality of interconnect layers;
a first interconnect layer of the plurality of interconnect layers, the first interconnect layer comprising a first conductive layer;
a second interconnect layer of the plurality of interconnect layers, the second interconnect layer comprising a second conductive layer; and
a via structure extending from the first conductive layer to the second conductive layer, the via structure comprising
a third conductive layer in contact with the first conductive layer,
a fourth conductive layer in contact with the second conductive layer, and
a dielectric structure between the third conductive layer and the fourth conductive layer,
wherein the via structure is offset from the first conductive layer and/or the second conductive layer such that only a portion of a bottom surface of the third conductive layer contacts the first conductive layer and/or only a portion of a top surface of the fourth conductive layer contacts the second conductive layer.

2. The integrated circuit of claim 1, wherein the dielectric structure comprises a layer comprising silicon and oxygen.

3. The integrated circuit of claim 1, wherein the first conductive layer and the second conductive layer each comprise copper or tungsten.

4. The integrated circuit of claim 1, wherein the third conductive layer and the fourth conductive layer each comprise any one of platinum, tungsten, gold, or titanium.

5. The integrated circuit of claim 1, wherein the via structure is offset by at least 25% such that at least 25% of the bottom surface of the third conductive layer does not contact the first conductive layer, and/or at least 25% of the top surface of the fourth conductive layer does not contact the second conductive layer.

6. The integrated circuit of claim 1, wherein the via structure is offset by at least 50% such that at least 50% of the bottom surface of the third conductive layer does not contact the first conductive layer, and/or at least 50% of the top surface of the fourth conductive layer does not contact the second conductive layer.

7. The integrated circuit of claim 1, wherein the via structure is offset by at least 99% such that less than 1% of the bottom surface of the third conductive layer contacts the first conductive layer, and/or less than 1% of the top surface of the fourth conductive layer contacts the second conductive layer.

8. A printed circuit board comprising the integrated circuit of claim 1.

9. An integrated circuit, comprising:
an interconnect region above a plurality of semiconductor devices, the interconnect region comprising a plurality of interconnect layers;
a first interconnect layer of the plurality of interconnect layers, the first interconnect layer comprising a first conductive layer extending lengthwise along a first direction;
a second interconnect layer of the plurality of interconnect layers, the second interconnect layer comprising a second conductive layer extending lengthwise along a second direction orthogonal to the first direction; and
a third interconnect layer of the plurality of interconnect layers between the first and second interconnect layers, the third interconnect layer comprising a dielectric layer and a via structure passing through the dielectric layer in a third direction different from the first and second directions, wherein the via structure comprises
a third conductive layer in contact with the first conductive layer,
a fourth conductive layer in contact with the second conductive layer, and
a dielectric structure between the third conductive layer and the fourth conductive layer,
wherein the via structure is offset from the first conductive layer along the second direction and/or is offset from the second conductive layer along the first direction.

10. The integrated circuit of claim 9, wherein the first conductive layer and the second conductive layer each comprise copper or tungsten.

11. The integrated circuit of claim 9, wherein the third conductive layer and the fourth conductive layer each comprise any one of platinum, tungsten, gold, or titanium.

12. The integrated circuit of claim 9, wherein the via structure is offset along the second direction by at least 99% such that less than 1% of a bottom surface of the third conductive layer contacts the first conductive layer, and/or the via structure is offset along the first direction by at least 99% such that less than 1% of a top surface of the fourth conductive layer contacts the second conductive layer.

13. The integrated circuit of claim 9, wherein the third direction is orthogonal to the first and second directions.

14. A printed circuit board comprising the integrated circuit of claim 9.

15. An electronic device, comprising:
a chip package comprising one or more dies, at least one of the one or more dies comprising
a plurality of semiconductor devices;
an interconnect region above the plurality of semiconductor devices, the interconnect region comprising a plurality of interconnect layers;
a first interconnect layer of the plurality of interconnect layers, the first interconnect layer comprising a first conductive layer;
a second interconnect layer of the plurality of interconnect layers, the second interconnect layer comprising a second conductive layer; and
a via structure extending between the first conductive layer and the second conductive layer, the via structure comprising
a third conductive layer in contact with the first conductive layer,
a fourth conductive layer in contact with the second conductive layer, and
a dielectric structure between the third conductive layer and the fourth conductive layer,
wherein the via structure is offset from the first conductive layer and second conductive layer such that only a portion of a bottom surface of the third conductive layer contacts the first conductive layer and only a portion of a top surface of the fourth conductive layer contacts the second conductive layer.

16. The electronic device of claim 15, wherein the dielectric structure comprises a layer comprising silicon and oxygen.

17. The electronic device of claim 15, wherein the first conductive layer and the second conductive layer each comprise copper or tungsten.

18. The electronic device of claim 15, wherein the third conductive layer and the fourth conductive layer each comprise any one of platinum, tungsten, gold, or titanium.

19. The electronic device of claim 15, wherein the via structure is offset by at least 99% such that less than 1% of the bottom surface of the third conductive layer contacts the first conductive layer, and/or less than 1% of the top surface of the fourth conductive layer contacts the second conductive layer.

20. The electronic device of claim 15, further comprising a printed circuit board, wherein the chip package is attached to the printed circuit board.
